(19) United States
(12) Patent Application Publication
(10) Pub. No.: US 2016/0229684 A1
(43) Pub. Date: Aug. 11, 2016

(54) MEMS DEVICE INCLUDING SUPPORT STRUCTURE AND METHOD OF MANUFACTURING

(71) Applicant: MOTION ENGINE INC., Montréal (CA)

(72) Inventor: Robert Mark Boysel, Montreal (CA)

(21) Appl. No.: 15/024,704

(22) PCT Filed: Sep. 23, 2014
(86) PCT No.: PCT/CA2014/050910

§ 371 Date: Mar. 24, 2016

Related U.S. Application Data
(60) Provisional application No. 61/881,643, filed on Sep. 24, 2013.

(51) Int. Cl. B81B 3/00; B81C 1/00

(52) U.S. Cl. CPC B81B 3/0078; B81C 1/00269; B81B 2203/0163; B81B 2207/092; B81B 2201/0235; B81B 2201/0242; B81C 2201/013

(57) ABSTRACT

A micro-electro-mechanical system (MEMS) device and a manufacturing method are provided. The device includes top and bottom cap wafers and a MEMS wafer disposed between the top cap wafer and the bottom cap wafer. The top, bottom and MEMS wafers define sidewalls of a cavity. A MEMS structure is housed within the cavity and is movable relative to the top and bottom caps. At least one electrode is provided in one of the wafers, the electrode being operatively coupled to the MEMS structure to detect or induce a movement thereof. A support structure extends through the cavity from the top cap wafer to the bottom cap wafer to prevent bowing in the top cap and bottom cap wafers.

### RELATED APPLICATIONS

This patent application claims priority from U.S. 61/881,643, the disclosures of which are incorporated herein, in their entirety, by reference.

### TECHNICAL FIELD OF THE INVENTION

The present invention generally relates to MicroElectroMechanical Systems (MEMS) devices and more specifically to a MEMS device for reducing sensitivity to external forces or pressure.

### BACKGROUND

Micro Electro Mechanical Systems (MEMS) devices, in particular accelerometers and angular rate sensors or gyroscopes (i.e. inertial sensors), are being used in a steadily growing number of applications. Due to the significant increase in consumer electronics applications for MEMS sensors such as smart phones, optical image stabilization (01S) for phones and cameras and wearable electronics there has been a growing interest in utilizing such technology for more advanced applications traditionally catered to by much larger, more expensive higher grade non-MEMS sensors. These applications include single and multiple axis devices for industrial applications, Inertial Measurement Units (IMUS) for navigation systems and Attitude Heading Reference Systems (AHRS), control systems for unmanned air, ground and sea vehicles and for precise personal indoor and even GPS-denied navigation. They also may include healthcare/medical and sports performance monitoring and advanced motion capture systems for next generation virtual reality. These advanced applications require lower bias drift and higher sensitivity specifications well beyond existing consumer-grade MEMS inertial sensors on the market. In order to expand these markets, the higher performance specifications must also be developed and addressed by producing a low cost and small size sensor and/or a MEMS inertial sensor-enabled system.

In general, a MEMS device must interact with a particular aspect of its environment while being protected from damage. For example, a micro mirror has to interact with light and an electrical addressing signal, while being protected from moisture and mechanical damage. An accelerometer has to be free to move in response to accelerated motion, but be protected from dirt and moisture, and perhaps also be kept under vacuum or low pressure to minimize air damping.

In many applications, MEMS devices are sensitive to variations in ambient pressure. In some cases, such as for pressure sensors, this sensitivity is desirable. However, in many other applications, sensitivity to outside pressure is undesirable as it interferes with the parameter actually being measured. This can be particularly problematic in the case of capacitive sensors which can respond to outside pressure or other external forces, such as those exerted during wire bonding if the device is not packaged carefully.

To illustrate the undesirable effects of pressure sensitivity, consider the particular example of a capacitive inertial sensor. The earliest forms of MEMS inertial sensors were accelerometers etched in bulk silicon wafers. These accelerometers consist of a large proof mass suspended from a thin compliant beam or spring. The mass and spring move in response to acceleration, and the movement is detected capacitively using the mass and cap (or caps) as capacitor plates. The change in position of the proof mass relative to the cap electrode is proportional to the acceleration being experienced by the proof mass. However, if the pressure outside the package is different from the pressure inside, the top electrode can flex, adding a non-inertial error term to the measurement. The amount of flex is proportional to Pw⁴/t³ where “P” is the pressure differential across the thickness of the cap and “w” and “t” are the width and thickness respectively of the unsupported portion of the cap.

Early accelerometers minimized the effects of pressure by using very thick cap electrodes and operating at atmospheric pressure. However, in state-of-the-art motion sensors, it is desirable to minimize the height of the packaged MEMS so that it can fit in consumer applications such as cell phones. Additionally, in order to use the same technology to fabricate a resonant gyroscope, the package must be at vacuum to minimize the damping of the proof mass motion.

Surface micromachining has helped to alleviate the pressure sensitivity of the cap and has helped to reduce the chip size. Surface micromachining techniques include the use of thin films to form MEMS structures. In particular, in surface micromachined inertial sensors, polycrystalline silicon is used to form the springs and proof mass in a single layer. With this arrangement, the proof mass moves laterally in response to x and y acceleration, and the motion is detected with comb capacitors. Since the capacitive detection between the proof mass and the cap is removed, they are less sensitive to outside pressure. However, since the MEMS material is deposited using thin film processes, the mechanical polysilicon films tend to be thin, on the order of a few microns rather than the hundreds of microns of bulk micromachined sensors. Thus, the proof mass and electrode area are small, reducing sensitivity and increasing mechanical noise.

In order to improve the performance of the described MEMS sensors, it is desirable to mitigate or reduce the pressure sensitivity of MEMS devices.

### SUMMARY OF THE INVENTION

In accordance with an aspect of the invention, a micro-electro-mechanical system (MEMS) device is provided. The MEMS device includes a top cap wafer, a bottom cap wafer and a MEMS wafer disposed between the top cap wafer and the bottom cap wafer. The top cap wafer, the bottom cap wafer and the MEMS wafer define sidewalls of a cavity or chamber. A MEMS structure is housed within the cavity and can move relative to the top and bottom caps. At least one electrode is provided in one of the top cap wafer, the MEMS wafer and the bottom cap wafer. This at least one electrode is operatively coupled to the MEMS structure to detect or induce a movement of the MEMS structure. A support structure extends through the cavity from the top cap wafer to the bottom cap wafer to prevent bowing in the top cap and/or bottom cap wafer(s).

In some embodiments, the support structure comprises a cap portion formed within the top cap wafer, a core portion formed within the MEMS wafer and a base portion formed within the bottom cap wafer.

In some embodiments, the top cap wafer, the bottom cap wafer and the MEMS wafer are made of electrically-conductive material.

In some embodiments, the top cap wafer, the bottom cap wafer and the MEMS wafer are made of silicon-based material.

In some embodiments, the support structure is electrically conductive.

In some embodiments, the top cap wafer has inner and outer sides, the MEMS wafer has first and second sides and the bottom cap wafer has inner and outer sides. The inner sides of the top and bottom cap wafers are electrically bonded to the first and second side of the MEMS wafer, respectively.

In some embodiments, the MEMS wafer is a silicon-on-insulator (SOI) wafer comprising a device layer, an insulating layer and a handle layer.

In some embodiments, the support structure includes a conducting shunt extending from the device layer to the handle layer, through the insulating layer. p In some embodiments, the support structure passes through the MEMS structure without interfering with movement of the MEMS structure.

In some embodiments, the MEMS structure is a suspended proof mass, preferably suspended by four flexural springs.

In some embodiments, at least one of the cap portion and the base portion is delimited by insulated closed-loop channels etched through the corresponding top or bottom cap wafer.

In some embodiments, the core portion is spaced away from the MEMS structure and surrounded by a clearance gap etched through the MEMS wafer.

In some embodiments, the cap wafer and the bottom cap wafer respectively include electrical contacts electrically connected to the support structure for transmitting electrical signals between the respective electrical contacts of the bottom cap and top cap wafers via the support structure.

In some embodiments, the MEMS device includes at least one additional support structure extending though the cavity from the top cap wafer to the bottom cap wafer.

In accordance with an aspect of the invention, a method for manufacturing a MEMS device is also provided. The method includes the steps of:
providing a top cap wafer and a bottom cap wafer having respective inner and outer sides, patterning in the top and bottom cap wafers respective cap and base portions of a support structure to be formed and respective top and bottom sidewalls of a cavity to be formed, and at least one electrode in one of the top and bottom cap wafers;
providing a MEMS wafer having first and second sides, and patterning on one of the first and second sides at least a part of a MEMS structure and a part of a core portion of the support structure;
bonding the side of the MEMS wafer patterned in the previous step to the inner side of one of the top and bottom cap wafers by aligning the corresponding cap or base portion to the part of the core portion of the MEMS wafer;
patterning on the other side of the MEMS wafer the remaining part of the MEMS structure, the remaining part of the core portion, and lateral sidewalls of the cavity; and
bonding the side of the MEMS wafer patterned the previous step to the inner side of the other one of the top and bottom cap wafers by aligning the top, lo bottom and lateral sidewalls to form the cavity housing the MEMS structure therein, the at least one electrode being operatively coupled to the MEMS structure, and by aligning the corresponding cap or base portion of said other cap wafer with the remaining part of the core portion, the support structure extending through the cavity from the bottom cap wafer to the top cap wafer to prevent bowing in the top cap and bottom cap wafers.

In some embodiments of the method, the top, bottom and MEMS wafer are electrically conductive, and the bonding steps are made with a conductive bond.

In some embodiments of the method, the cap and base portions are formed by etching trenches in the respective inner sides and at least partially through the top and bottom cap wafers, and by filling the trenches with an insulating material or an insulating lining followed by a conductive fill.

In some embodiment, the method includes a step of removing a portion of the outer sides of the top and bottom cap wafers to isolate the at least one electrode and the cap and base portions.

In some embodiments, the method includes a step of forming first and second electrical contacts on the outer sides of the top and bottom cap wafers, respectively, the first electrical contact being electrically connected to the cap portion and the second electrical contact being electrically connected to the bottom cap portion.

In some embodiments, the method includes the patterning a clearance gap within parts of the MEMS structure to form the support structure, such that after completing the MEMS device, the support structure passes through the MEMS structure.

In some embodiments of the method, the MEMS wafer is an SOI wafer with an insulating layer separating a device layer from a handle layer, the method comprises forming a conducting shunt between the device and handle layers in said part of the core portion.

Advantageously, some embodiments of the MEMS device and of the method take advantage of larger masses and electrode areas available through micromachined inertial sensors. Some embodiments of the present invention also allow minimizing the height of the MEMS device. Some embodiments of the present invention allow mitigating or reducing the pressure sensitivity of a MEMS packaging, and in particular, they take advantage of the larger masses and electrode areas available with bulk micromachined inertial sensors without having to worry about errors introduced by cap electrode flexing due to pressure variations.

### DESCRIPTION OF THE DRAWINGS

It should be noted that the appended drawings illustrate only exemplary embodiments of the invention and should therefore not be considered limiting of its scope, as the invention may admit to other equally effective embodiments.

FIG. 1 is a schematic perspective view of a MEMS device, according to a possible embodiment. FIG. 1A is a schematic cross-sectional view of the MEMS device of FIG. 1, taken along line A-A

FIG. 2 is a schematic exploded perspective view of the MEMS device of FIG. 1. FIG. 2A is a schematic exploded cross-sectional view of the MEMS device of FIG. 1. FIG. 2B is a schematic exploded cross-sectional view of a MEMS device according to another possible embodiment.

FIG. 3 is a schematic top view of the MEMS wafer of the MEMS device of FIG. 1.

FIG. 4 is a schematic top view of a top cap wafer of the MEMS device of FIG. 1. FIG. 4A is a cross-sectional view of the top cap wafer of FIG. 4, during the manufacturing process. FIG. 4B is another cross-sectional view of the top cap wafer of FIG. 4, during another step of the process, according to a possible embodiment.

FIG. 5A is a cross-sectional view of the bottom cap wafer of the MEMS device of FIG. 1, during the manufacturing process, according to a possible embodiment.

FIG. 6 is a schematic top view of a MEMS wafer of the device of FIG. 1. FIG. 6A is a cross-sectional view of the MEMS wafer of FIG. 6, during the manufacturing process. FIG. 6B is another cross-sectional view of the MEMS wafer of FIG. 6, during another step of the process, according to a possible embodiment.

FIG. 7 is a schematic top view of the MEMS wafer of the device of FIG. 1. FIG. 7A is a cross-sectional view of the MEMS wafer of FIG. 7, during the manufacturing process.

FIG. 8 is a schematic exploded view of the top cap wafer of FIG. 4 and of the MEMS wafer of FIG. 7. FIG. 8A is a cross-sectional view of the top cap and MEMS wafers of the MEMS device of FIG. 1, during the manufacturing process, showing the bonding of the top cap wafer to the MEMS wafer.

FIG. 9 is a schematic top view of the MEMS wafer and of the top cap wafer of the MEMS device of FIG. 1, during a possible step of the manufacturing process. FIG. 9A is a cross-sectional view of the MEMS wafer bonded to the top cap wafer shown in FIG. 9.

FIG. 10 is a schematic exploded perspective view of the bottom cap wafer and of the MEMS wafer bonded to the top cap wafer of the device of FIG. 1, during a possible step of the manufacturing process. FIG. 10A is a cross-sectional view of the top and bottom cap wafers bonded to the MEMS wafer of FIG. 10.

FIG. 11 is a schematic perspective view of the device of FIG. 1, during the manufacturing process. FIG. 11A is a cross-sectional view of the device of FIG. 1, during a possible manufacturing step.

FIG. 12 is a schematic perspective view of the device of FIG. 1. FIG. 12A is a cross-sectional view of the device of FIG. 12.

### DETAILED DESCRIPTION OF AN EMBODIMENT OF THE INVENTION

The present invention provides a micro-electro mechanical system (MEMS) device, such as a sensor or an actuator, whose architecture includes a support structure that enables a thin cap to be used as part of the MEMS device. The support structure advantageously allows minimizing the sensitivity of the cap to pressure or other forces. The present invention also provides a method for manufacturing such a MEMS device. In an exemplary embodiment, the support structure allows to reduce or prevent flexure of cap electrodes and pressure sensitivity in a three-dimensional (3D) motion sensor, which can include one or several pendulous proof mass or masses. The support structure is preferably fabricated using a 3D packaging architecture which can also provide, in addition to mechanical support, isolated electrical pathways through the package. The support structure can include a three-dimensional through-chip-via, so as to provide an access extending through the several wafer(s) forming the MEMS device to route electrical signals through the MEMS device. Throughout the description, the term MEMS encompasses devices such as, but not limited to, accelerometers, gyroscopes, pressure sensors, magnetometers, microphones, actuators, micro-fluidic, micro-optic devices and the like. The MEMS wafer may also include microelectronic circuits such as power amplifiers, detection circuitry, GPS, microprocessors, and the like.

In the present description, the terms “top” and “bottom” relate to the position of the wafers as shown in the figures. Unless otherwise indicated, positional descriptions such as “top”, “bottom” and the like should be taken in the context of the figures and should not be considered as being limitative. The top cap wafer can also be referred as a first cap wafer, and the bottom cap wafer can be referred as a second cap wafer. The terms “top” and “bottom” are used to facilitate reading of the description, and persons skilled in the art of MEMS know that, when in use, MEMS devices can be placed in different orientations such that the “top cap wafer” and the “bottom cap wafer” are positioned upside down. In this particular embodiment, the “top” refers to the direction of the device layer.

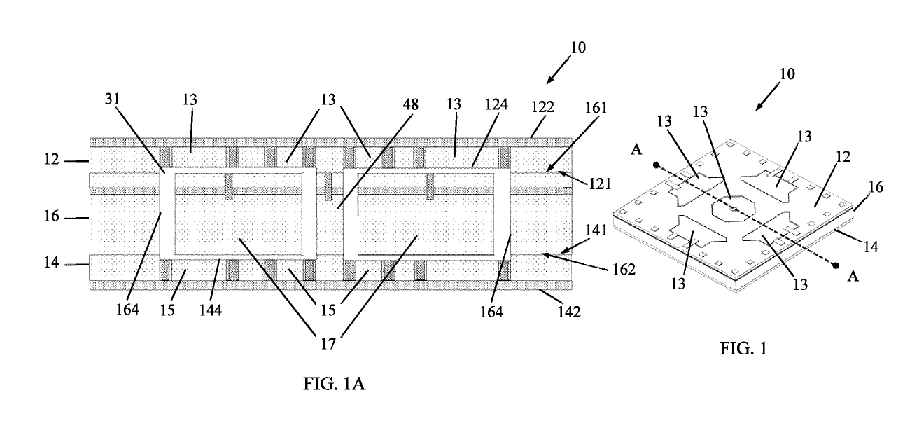

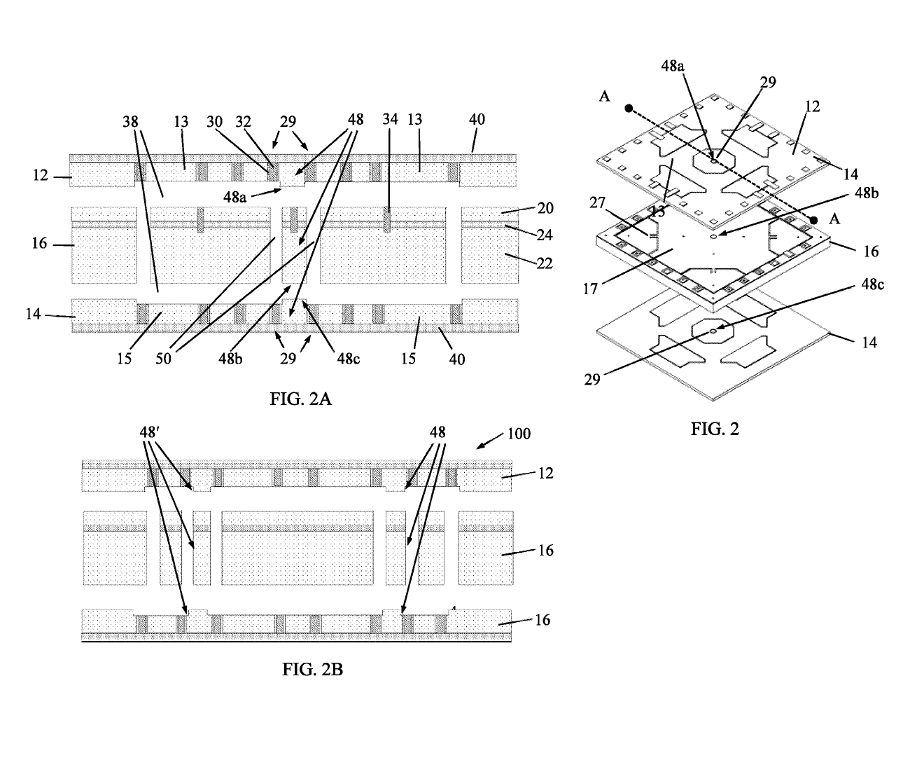

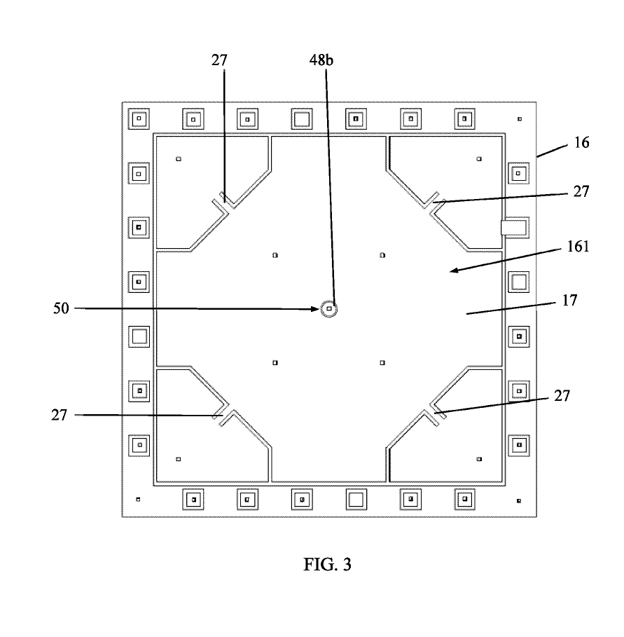

Referring to FIGS. 1 and 1A, a possible embodiment of a micro-electro-mechanical system (MEMS) device 10 is shown. The MEMS device can also be referred to as a MEMS package. The MEMS device 10 includes a top cap wafer 12 and a bottom cap wafer 14 and a MEMS wafer 16 disposed between the top and bottom cap wafers 12, 14. The top cap wafer 12 has inner and outer sides 121, 122, the MEMS wafer 16 has first and second sides 161, 162 and the bottom cap wafer 14 has inner and outer sides 141, 142. The inner sides 121, 141 of the top and bottom cap wafers 12, 14 are preferably electrically bonded to the first and second side 161, 162 of the MEMS wafer 16, respectively. The top cap wafer 12, the bottom cap wafer 14 and the MEMS wafer 16 define sidewalls 124, 164, 144 of a cavity or chamber 31. The three wafers 12, 16, 14 are bonded together, preferably under vacuum, to provide a hermetically sealed cavity 31. A MEMS structure 17 is housed within the cavity 31 and can move relative to the top and/or bottom caps 12, 14. A MEMS device or package configured as such thus includes elements surrounding and/or protecting MEMS structure such as a sensor or an actuator. In this particular embodiment, the MEMS device 10 is a motion sensor, and the MEMS structure 17 is a bulk proof mass suspended by flexible springs (not visible in this cross-section, but shown in FIG. 3) which are themselves connected to an outer frame formed at least partially by the MEMS wafer 16. At least one electrode is provided in one of the top cap wafer 12, the MEMS wafer 16 and the bottom cap wafer 14. The electrode(s) is/are operatively coupled to the MEMS structure 17 to detect or induce a movement of the structure. By operatively coupled, it is meant that the electrode is capacitively, electrically and/or magnetically connected or linked to the MEMS structure 17. Typically, the MEMS device 10 will include several electrodes located within the top, bottom or MEMS wafer so as to be able to detect a movement of the structure 17. In the present embodiment, the MEMS device 10 includes five top electrodes 13 (identified in FIG. 1) and five bottom electrodes 15 (best shown in FIG. 2). The electrodes 13, 15 form capacitors with the MEMS structure 17.

The MEMS device 10 also includes a support structure 48, or post, extending through the cavity 31 from the top cap wafer 12 to the bottom cap wafer 14 to prevent bowing in the top cap 12 and/or the bottom cap 14 wafers. The support structure 48 spans the height of the MEMS device 10, from bottom cap 14 to top cap 12 and can, when necessary, penetrate the MEMS movable structure 17, preferably without inhibiting its motion. In the present embodiment, insulated vias or channels etched within the different wafer layers allows the creation of a mechanical support 48 which prevents the top and bottom caps 12, 14 from deforming and/or flexing. This support structure 48 is preferably formed of a conducting material, such that the support structure 48 can transmit, control and/or inhibit flow of current passing through it, which may or may not be desirable according to different applications in which the MEMS device 10 is used. The support structure 48 can thus be used for both its mechanical and electrical properties.

Referring to FIGS. 2 and 2A, the support structure 48 preferably includes a cap portion 48a formed within the top cap wafer 12, a core portion 48b formed within the MEMS wafer 16 and a base portion 48c formed within the bottom cap wafer 14. At least one of the cap portions 48a, 48c is delimited by an insulated closed-loop channel 29 etched through the cap wafer 12 and/or 14. The cap and base portions 48a, 48b are preferably isolated from the remainder of the wafer caps. In the present case, the channels 29 are lined with an insulating material 30, such as silicon dioxide (SiO₂) or any other suitable material. The channel may also be optionally filled with a conducting material 32 including one of metal (e.g., copper), silicon and polysilicon. Alternatively, the channel 29 could be filled only with an insulating material. The core portion 48b is spaced away from the MEMS structure 17, and surrounded by a gap 50 etched through the MEMS wafer 16.

The top cap wafer 12, the bottom cap wafer 14 and the MEMS wafer 16 are preferably made of electrically-conductive material, such as a silicon-based material. The MEMS wafer 16 is preferably a silicon-on-insulator (SOI) wafer, which includes a device layer 20, an insulating layer 24 and a handle layer 22. In this case, the support structure 48 may include conducting shunts 34 (or electrical SOI vias) extending from the device layer 20 to the handle layer 22 through the insulating layer 24, making the core portion 48b electrically conductive over its entire length. The support structure 48 passes through the MEMS structure 17 without interfering with the movement of the MEMS structure 17. In the present embodiment, the support or post 48 is centered within the MEMS structure 17, which in this embodiment consists in a proof mass 17. However, in other embodiments, it is possible for the support structure to be located off-center relative to the MEMS structure 17, for example it could be located near one side of the MEMS structure 17.

The sense electrodes 13, 15 are isolated by insulating channels and sense capacitor gaps 38 are provided in both the top and bottom caps 12, 14. The inertial sensor's MEMS structure 17 consisting of a proof mass and suspension spring (not visible in this cross-section) is fabricated in the device layer 20 of the SOI wafer 16. Various insulated conducting pathways can be provided in the MEMS device. The insulated conducting pathways can be referred to as three-dimensional though-chip-vias (3DTCVs). The pathways are constructed by aligning feedthrough structures on each level of the MEMS device. Sections of the pathways are thus provided in the MEMS wafer to conduct electrical signals between the top and bottom caps. Some of the pathways can, for example, pass through the support structure 48. Conducting shunts or plugs 34 can be provided through the insulating layer 24 (typically buried oxide (BOx)) in the MEMS wafer 16 between the device layer 20 and handle layer 22, in select places to provide a conducting path from the bottom cap to the top cap. Where an insulating mechanical support is required, the conducting plugs 34 can be omitted.

When the sense capacitor gaps 38 are etched in the top and bottom caps 12, 14, silicon is left unetched at the desired location of the support structure to form cap 48a and base 48c portions of the support structure. Additionally, a clearance gap 50, which serves to separate the support structure 48 from the surrounding MEMS structure 17, is etched around the core portion of the support 48b in the MEMS wafer. The clearance gap 50 can be provided in many shapes and can for example be annular in shape. While it is preferable to provide at least one support in the center of the MEMS structure, as illustrated in FIG. 2A, it is also possible to form one or more supports 48 in other locations, as per FIG. 2B, which shows an alternate embodiment of a MEMS device 100. The MEMS device can include at least one additional support structure 48′ extending though the cavity 31 from the top cap wafer 12 to the bottom cap wafer 14. The support(s) 48, 48′ can also have other configurations and/or shapes; however, a circular pillar shape is preferred, since it allows for providing a uniform clearance gap 50 around the support 48 for the proof mass to move. Of course, other shapes are possible, such as a rectangular post for example.

It is desirable to minimize the thickness of the caps to more easily fabricate through-cap structures such as electrical vias and electrodes and to reduce the overall height of the completed device. For example, the top cap wafer can have a thickness on the order of 100 um to 200 um, while the MEMS wafer has a thickness between 50 and 700 um, and therefore the proof mass will also typically measure between 50 and 700 um in thickness. As the ratio of the cap width to cap thickness increases, the device becomes more and more sensitive to pressure. However, by placing a support structure or post 48, preferably at the center of the device, the device can be made about sixteen times less sensitive to pressure due to the width⁴ (w⁴) dependence. By placing additional supports between the center and edge, preferably symmetrically, the sensitivity can be reduced even further.

FIG. 3 shows the first face 161 of the MEMS wafer 16, with a portion of the support structure passing through the proof mass 17, suspended by four flexural springs 27. The core 48b and clearance gap 50 comprise a 3DTCV with the core 48b forming the central support between the caps. The clearance gap 50, which in this embodiment as of annular shape, is preferably wide enough to not interfere with the motion of the proof mass 17. For the inertial sensor described here in operation, the full scale angular translation of the proof mass is typically around 4 mrad. As an example, motion of a thick proof mass with a thickness on the order of 400 μm may result in a lateral translation of less than 2 μm, i.e. much less than the typical minimum 20-50 μm width required to etch a channel through a silicon wafer. Additionally, in order to avoid disturbing the proof mass 17 electrostatically, it is preferable to include a conducting plug through the insulating layer (typically buried oxide) to control the potential of the support and avoid charging effects.

Manufacturing Method

Fabrication of the present invention will be described in connection with a preferred embodiment, however, it will be understood that there is no intent to limit the invention to the embodiment described. On the contrary, the intent is to cover all alternatives, modifications, and equivalents as may be included within the spirit and scope of the invention as defined by this specification, drawings, and the appended claims.

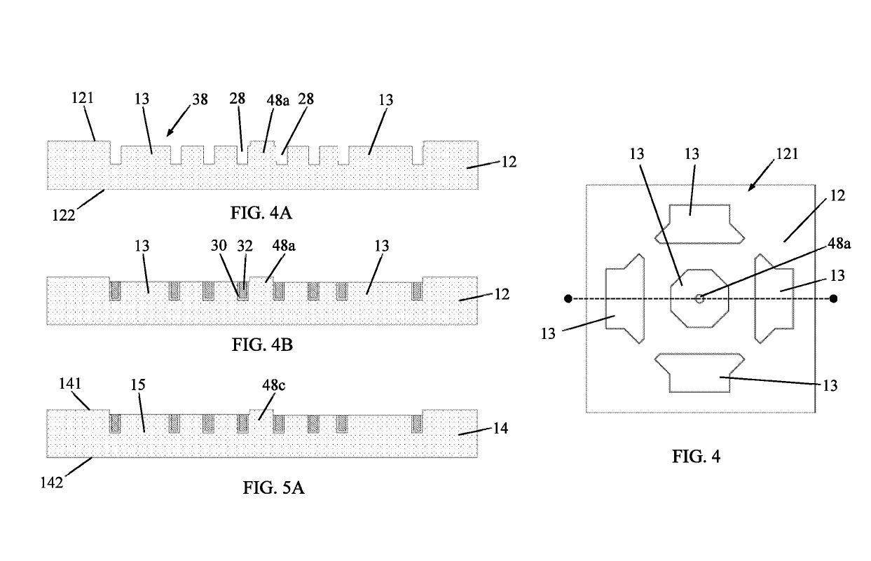

Referring to FIGS. 4 to 12, and broadly described, the method includes the steps of providing a top cap wafer 12 and a bottom cap wafer 14 and then patterning: cap and base portions 48a, 48c of the support structure; top and bottom sidewalls 124, 144 of the cavity 31, and at least one electrode 13 and/or 15 in one of the top and bottom cap wafers. The method also includes a step of providing a MEMS wafer 16 and patterning on one of its sides at least a part of a MEMS structure 17 and a part of a core portion 48b of the support structure. The method includes bonding the mentioned side of the MEMS wafer to the inner side of one of the top and bottom cap wafers 12, 14 by aligning the corresponding cap or base portion 48a or 48c of the support structure with the part of the core portion 48b of the support structure previously patterned in the MEMS wafer. The method then includes patterning the other side of the MEMS wafer with the remaining part of the MEMS structure 17, the remaining part of the core portion 48b, and lateral sidewalls 164 of the cavity. The method then includes bonding this other side of the MEMS wafer to the other cap wafer 12, 14, by aligning the top, bottom and lateral sidewalls to form the cavity, housing the MEMS structure 17 therein. With the top and bottom cap wafers 12, 14 bonded to the MEMS wafer 16, the electrode(s) are operatively coupled to the MEMS structure 17, and by aligning the cap or base portion 48c, 48a with the remaining part of the core portion 48b, the support structure 48 extends through the cavity 31 from the bottom cap wafer 12 to the top cap wafer 14, advantageously preventing bowing in the top cap 12 and bottom cap 14 wafers. Possible implementations of each step of the method will be described in more detail below.

Referring to FIGS. 4 and 4A-4B, the capacitor gap 38 is first etched into the top cap wafer 12. An island of silicon is left at the location of the cap portion 48a of the future support structure, the cap portion 48a having the same height as the cap periphery, so that the cap portion 48a will contact the MEMS wafer during wafer bonding. The boundary of the top cap wafer 12 is then patterned with the electrode pattern, to delineate the different electrodes 13. The cap portion is thus formed by etching trenches 28 on the inner side 121 of the top cap wafer 12 and at least partially through wafer 12. The trenches 28 are then lined with an insulating material 30, followed by a conductive fill 32. Alternatively, the trenches 28 can be filled with an insulating material 30 only.

Referring to FIG. 5A, these steps are repeated on a second or bottom cap wafer 14 to form the bottom cap electrode pattern, with electrodes 15 and the support base portion 48c.

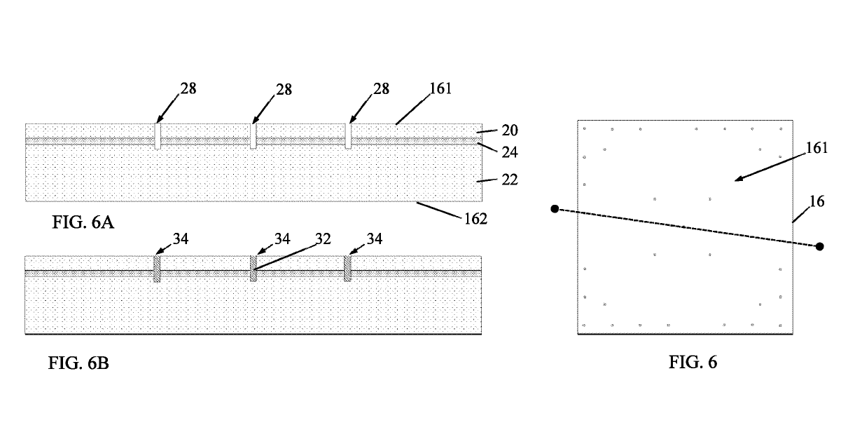

Referring to FIGS. 6 and 6A-6B, the MEMS wafer 16 is provided. In the present embodiment, the MEMS wafer 16 is a SOI wafer with an insulating layer 24 separating a device layer 20 from a handle layer 22. Trenches 28 are etched on the first side 161 (corresponding to the side of the device layer 20) through the insulating layer 24 or slightly into the SOI Handle layer 22. The trench is filled with a conductive material 32, such as metal, doped polycrystalline silicon (polysilicon), or other conducting material. In this way an electrical path 34 is formed vertically between the SOI Device and Handle layers 20, 22 at desired spots.

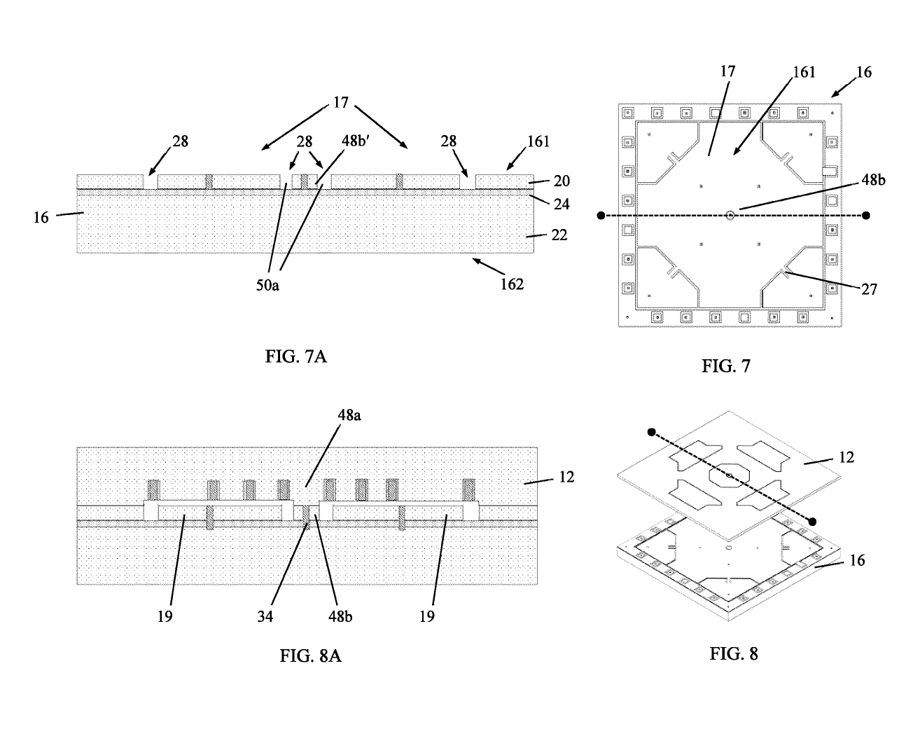

Referring to FIGS. 7 and 7A, the side 161 is then patterned with trenches to delimit a portion of the MEMS structure 17 and a portion 48b′ of the core portion of the support structure. The trenches delimiting the portion 48b′ of the core portion of the support structure form a portion 50a of the annular clearance gap. Other elements can also be patterned in order to define any other desired MEMS structures. Such other structures can include springs 27 and the top of the proof mass 17, leads, and feedthroughs, delimited by trenches 28 in the SOI device layer 20.

Referring to FIGS. 8 and 8A, the top cap wafer 12 is then aligned and bonded to the side of the MEMS wafer patterned in the previous step, which in this case corresponds to the SOI device layer 20. The cap portion of the support structure 48a is thereby aligned and bonded to the portion 48b′of the core portion of the support structure which has been partially etched in the SOI device layer 22. Additionally, the electrodes 13 on the top cap 12 are aligned to the relevant electrodes 19 in the MEMS wafer 16. The wafer bonding process used provides a conductive bond, and may include processes such as fusion bonding, gold thermocompression bonding, or gold-silicon eutectic bonding.

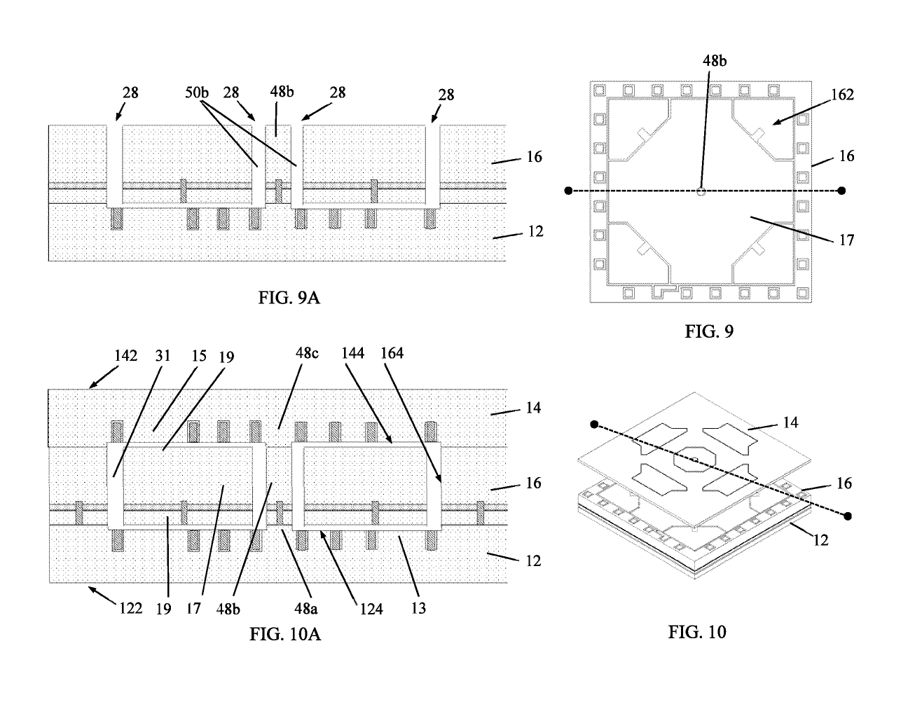

Referring to FIGS. 9 and 9A, the other side of the MEMS wafer 16, corresponding in this case to the SOI handle layer 22, is next patterned with trenches 28 to form the portion 50b of the clearance gap, defining the remainder of the core portion 48b of the support structure in the proof mass 17. Trenches 28 are also formed to delimit the lateral sides of the proof mass 17, as well as any additional MEMS structures, such as peripheral 3DTCV feedthroughs.

Referring to FIG. 10, the bottom cap wafer 14 is next bonded to the backside of the MEMS wafer 16, i.e. in this case to the SOI handle layer 22, again using a conductive a wafer bonding method.

As best shown in FIG. 10A, the support structure base 48c is thereby bonded to the rest of the support structure 48a, 48b for forming the conductive mechanical support 48, from the bottom cap 14, through the MEMS structure 16, and to the top cap 12. In the same way, conductive paths can be provided from the bottom electrodes, through the bottom cap wafer, handle feedthroughs, conducting shunts, and SOI device layer 20 to the top cap wafer 12. At this point, the cavity 31 and the MEMS structure 17 are hermetically sealed between the cap wafers 12, 14. The electrodes 13, 15, 19 are aligned and the top cap and bottom cap are supported by the central support structure 48 and by the outer frame of the device. However, the electrodes in the top and bottom caps are still shorted by the silicon of the top and bottom cap wafer extending beyond the insulated trenches.

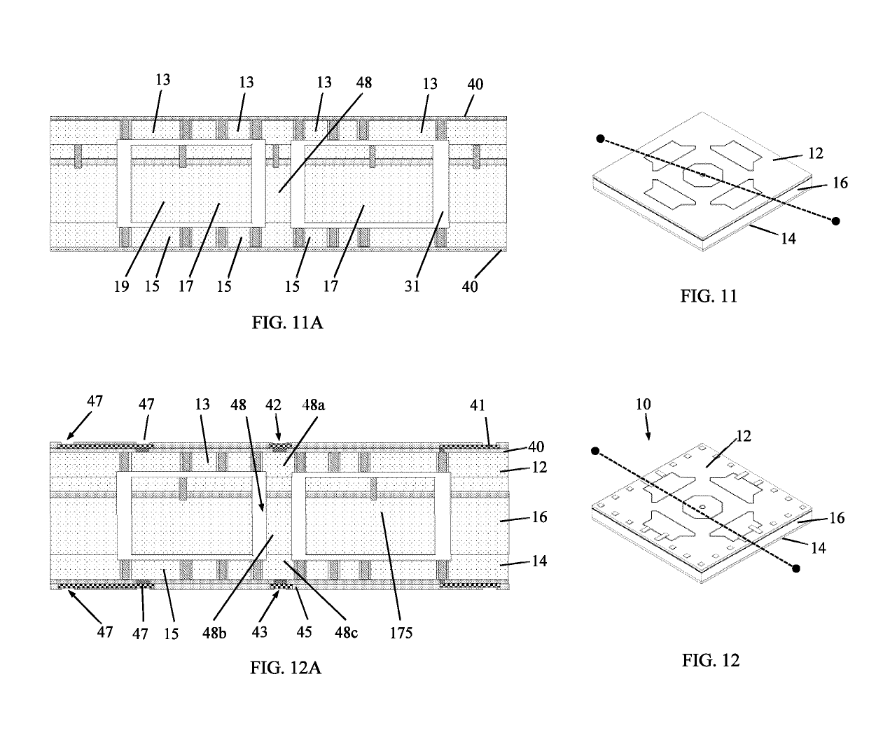

Referring to FIGS. 11 and 11A, the present method includes a step of removing a portion of the outer sides 122, 142 of the top and bottom cap wafers 12, 14 to isolate the electrodes and the cap and base portions of the support structure 48. More specifically, both cap wafers 12, 14 are ground and polished to expose the insulated channels. The support cap and base portions 48a, 48c, as well as electrodes are thereby electrically isolated except for the connections to the top cap pads through the feedthroughs and silicon vias. Both outer surfaces 122, 142 are passivated with an insulating oxide layer 40 to protect them.

Referring to FIGS. 12 and 12A, first and second electrical contacts 42, 43 are formed on the outer sides 122, 142 of the top and bottom cap wafers 12, 14, the first electrical contact 42 being electrically connected to the cap portion 48a of the support structure and the second electrical contact 43 being electrically connected to the bottom cap portion 48c of the support structure. More specifically, openings are made in the insulating layer 40 and a metallic layer 41 is deposited and patterned in predetermined locations, for forming leads and electrical pads. A passivating layer 45 can then be applied, and openings are made in the passivating layer to expose the electrical contacts 42, 43 (typically bond pads). Additional contacts 47 can be formed, in electrical connection with the electrodes 13 or 15, or peripheral feedthroughs. In this way, electrical connections from the top, sides, and bottom of the MEMS are accessible from the top of the MEMS device 10 for wire bonding, flip chip bonding, or wafer bonding.

Of course, other processing steps may be performed prior, during or after the above described steps. The order of the steps may also differ, and some of the steps may be omitted or combined.

The scope of the claims should not be limited by the preferred embodiments set forth in the examples, but should be given the broadest interpretation consistent with the description as a whole.

1. A micro-electro-mechanical system (MEMS) device comprising:
a top cap wafer and a bottom cap wafer;
a MEMS wafer disposed between the top cap wafer and the bottom cap wafer, the top cap wafer, the bottom cap wafer and the MEMS wafer defining sidewalls of a cavity;
a MEMS structure housed within the cavity and movable relative to the top and bottom caps;
at least one electrode provided in one of the top cap wafer, the MEMS wafer and the bottom cap wafer, said at least one electrode being operatively coupled to the MEMS structure to detect or induce a movement thereof; and
a support structure extending through the cavity from the top cap wafer to the bottom cap wafer to prevent bowing in the top cap wafer and bottom cap wafer.

2. The MEMS device according to claim 1, wherein the support structure comprises a cap portion formed within the top cap wafer, a core portion formed within the MEMS wafer and a base portion formed within the bottom cap wafer.

3. The MEMS device according to claim 1, wherein the top cap wafer, the bottom cap wafer and the MEMS wafer comprises an electrically-conductive material.

4. The MEMS device according to claim 1, wherein the top cap wafer, the bottom cap wafer and the MEMS wafer comprises a silicon material.

5. The MEMS device according to claim 1, wherein the support structure is electrically conductive.

6. The MEMS device according to claims 1, wherein the top cap wafer has an inner side and an outer side, the MEMS wafer has a first side and a second sides and the bottom cap wafer has an inner side and an outer sides, the inner sides of the top cap wafer and bottom cap wafers being electrically bonded to the first side and the second side of the MEMS wafer, respectively.

7. The MEMS device according to any claim 1, wherein the MEMS wafer is a silicon-on-insulator (SOI) wafer comprising a device layer, an insulating layer and a handle layer.

8. The MEMS device according to claim 7, wherein the support structure comprises a conducting shunt extending from the device layer to the handle layer, through the insulating layer.

9. The MEMS device according to claim 1, wherein the support structure passes through the MEMS structure without interfering with movement of the MEMS structure.

10. The MEMS device according to claim 1, wherein the MEMS structure is a suspended proof mass.

11. The MEMS device according to claim 2, wherein at least one of the cap portion and the base portion is delimited by insulated closed-loop channels etched through the top cap wafer or the bottom cap wafer.

12. The MEMS device according to claim 2, wherein the core portion is spaced away from the MEMS structure and surrounded by a clearance gap etched through the MEMS wafer.

13. The MEMS device according to claim 1, wherein the top cap wafer and the bottom cap wafer further comprise electrical contacts electrically connected to the support structure for transmitting electrical signals between the electrical contacts of the bottom cap and the top cap wafers through the support structure.

14. The MEMS device according to claim 1, comprising at least one additional support structure extending through the cavity from the top cap wafer to the bottom cap wafer.

15. A method for manufacturing a MEMS device, the method comprising the steps of:
bonding a MEMS wafer to one of a top cap wafer and a bottom cap wafer, the top cap wafer having an inner side and an outer sides, patterning in the top cap wafer and bottom cap wafers, a cap portion and a base portion of a support structure to be formed and a top sidewall and a bottom sidewall of a cavity to be formed, and at least one electrode in one of the top cap wafer and bottom cap wafer;
the MEMS wafer having a first side and a second side and patterning on one of the first side and the second sides at least a part of a MEMS structure and a part of a core portion of the support structure;
bonding the patterned side of the MEMS wafer to the inner side of one of the top cap wafer and the bottom cap wafer by aligning the corresponding cap portion or base portion to the part of the core portion of the MEMS wafer;
patterning on the second side of the MEMS wafer a further part of the MEMS structure, a further part of the core portion, and lateral sidewalls of the cavity; and
bonding the second side of the MEMS wafer to the inner side of a further one of the top cap wafer and the bottom cap wafer by aligning the top sidewall, bottom sidewall and lateral sidewall to form the cavity housing the MEMS structure, the at least one electrode being operatively coupled to the MEMS structure, and by aligning a cap portion or base portion of said further cap wafer with a further part of the core portion, the support structure extending through the cavity from the bottom cap wafer to the top cap wafer to prevent bowing in the top cap wafer and bottom cap wafer.

16. The method for manufacturing a MEMS device according to claim 15, wherein the top, bottom and MEMS wafer are electrically conductive, and wherein the bonding steps are made with a conductive bond.

17. The method for manufacturing a MEMS device according to claim 15, wherein the cap portion and base portion are formed by etching trenches in the respective inner sides and at least partially through the top cap wafer and bottom cap wafer, and by filling the trenches with an insulating material or an insulating lining followed by a conductive fill.

18. The method for manufacturing a MEMS device according to claim 15, comprising a step of removing a portion of the outer sides of the top cap wafer and bottom cap wafer to isolate the at least one electrode and the cap portion and base portion.

19. The method for manufacturing a MEMS device according to claim 15, comprising a step of forming a first electrical contact and second electrical contacts on the outer sides of the top cap wafer and bottom cap wafer, respectively, the first electrical contact being electrically connected to the cap portion and the second electrical contact being electrically connected to the bottom cap portion.

20. The method for manufacturing a MEMS device according to claim 15, wherein the bonding steps comprise patterning a clearance gap within one or more parts of the MEMS structure to form the support structure, and wherein after the step of bonding the second side, the support structure passes through the MEMS structure.

21. The method for manufacturing a MEMS device according to claim 15, wherein the MEMS wafer is an SOI wafer with an insulating layer separating a device layer from a handle layer, the method further comprising a step of forming a conducting shunt between the device layer and the handle layer in said part of the core portion.
